(19) United States
(12) Patent Application Publication
(10) Pub. No.: US 2008/0088040 A1
(43) Pub. Date: Apr. 17, 2008

(54) Method for fabricating conformal electrodes using non-wettable surface and liquid metal

(76) Inventors: Avto Tavkhelidze, Tbilisi (GE); Zaza Taliashvili, Tbilisi (GE)

Correspondence Address: BOREALIS TECHNICAL LIMITED, 23545 NW SKYLINE BLVD, NORTH PLAINS, OR, 97133-9204, US

(21) Appl. No.: 11/974,313

(22) Filed: Oct. 12, 2007

(30) Foreign Application Priority Data
Oct. 13, 2006 (GB) GB0620350.9

(51) Int. Cl. H01L 23/58

(52) U.S. Cl. 257/798

(57) ABSTRACT

A diode device is disclosed that comprises a non-wettable electrode, a wettable electrode and a liquid metal disposed between the electrodes. The diode device may additionally comprise a non-wettable housing, preferably cylindrical. The diode device may additionally comprise a piston means able to change a volume of the liquid metal. In a preferred embodiment, the liquid metal has a low work function. The low function metal may be, for example, cesium. In a preferred embodiment, the liquid metal contains gallium.

### CROSS-REFERENCE TO RELATED APPLICATIONS

This application claims the benefit of U.K. Patent Application No. GB0620350.9, filed Oct. 13, 2006.

### BACKGROUND OF THE INVENTION

This invention relates to tunnel junctions.

Any liquid, including liquid metals, have surfaces that they wet, and surfaces that they do not wet. For example, liquid gallium will wet a silicon surface, but it will not wet a silica surface. Thus if a droplet of liquid gallium is placed on a silicon surface it will wet it and the droplet will assume a substantially flat shape. If the same droplet of liquid gallium is placed on the surface of silica, it will form almost spherical droplet. The physical mechanism of wettability is connected with interaction between surface and liquid atoms and could be ascribed to van der Waals forces between the atoms (molecules) of the two. In the case of the wettable pair (liquid metal and solid surface) the molecules of surface attract the molecules of liquid metal. In the case of non-wettable pair molecules of surface repel molecules of liquid metal. In the case of non-wettable pair there is no direct contact between the droplet and surface molecules. The absence of direct contact leads to such effects as very low friction and very low diffusion of liquid metal molecules into the surface.

### BRIEF SUMMARY OF THE INVENTION

In broad terms, the present invention is concerned with the use of a non-wettable liquid/solid pair in thermotunnel devices. It is particularly concerned with the situation in which both the solid surface and the liquid metal are electrically conductive, and the pair could be used as electrodes of thermotunnel devices. Because of the weak interaction between the molecules of the non-wettable pair, heat conductivity of the junction is very low. In addition, because of the very short distance between the molecules of the liquid metal and the solid surface, the probability of electron tunneling between them is high. Thus, in one aspect, the present invention is a tunnel junction having high electron tunneling probability and low thermal conductivity. This is ideal for thermotunnel devices. In a further aspect the present invention the liquid metal of the non-wettable pair junction repeats the shape of the solid surface and provides conformal electrodes.

Thus the present invention is a diode device comprising: a first electrode, a second electrode and a liquid metal disposed between the electrodes, in which the liquid metal is in contact with the first and second electrodes, and the liquid metal does not wet said first electrode. The diode device may additionally comprise a non-wettable housing, preferably cylindrical. The diode device may additionally comprise a piston means able to change a volume of the liquid metal.

In a preferred embodiment, the liquid metal has a low work function. The low function metal may be, for example, cesium.

In a preferred embodiment, the liquid metal contains gallium.

### BRIEF DESCRIPTION OF THE SEVERAL VIEWS OF THE DRAWING

For a more complete explanation of the present invention and the technical advantages thereof, reference is now made to the following description and the accompanying drawing in which:

FIG. 1 shows a possible design of non-wettable thermotunnel device of the present invention; and

FIG. 2 shows a further embodiment of the present invention having a piston to change the volume of liquid metal and to regulate inter-electrode distance.

### DETAILED DESCRIPTION OF THE INVENTION

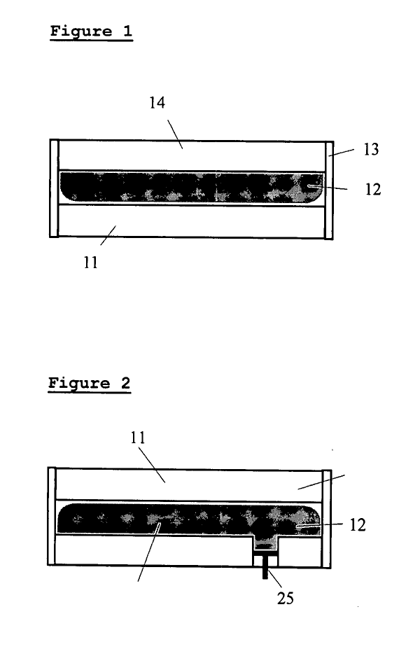

Embodiments of the present invention and their technical advantages may be better understood by referring to FIG. 1, which shows one embodiment of a non-wettable thermotunnel device. According to this embodiment, liquid metal 12 is disposed between first electrode 11 and second electrode 14. The properties of the liquid metal are such that it wets only electrode 14, which means that there is little or no direct thermal and electric contact between the liquid metal and the surface of electrode 11, allowing electrons to tunnel from electrode 11. In a preferred embodiment, the housing is cylindrical.

The advantage of this design is that there is no need to provide additional inter-electrode distance regulation. Distance between the non-wettable solid electrode and the liquid metal will remain constant, despite thermal expansions and vibrations. Thermal expansion of the parts will change the curvature of liquid metal on the perimeter a little bit. Thus piezoelectric regulators and associated electronics may be dispensed with.

According to this design, gravitational force acts to increase the non-wettable junction gap.

Referring now to FIG. 2, which shows a further embodiment of the present invention having a means to regulate inter-electrode distance, a piston 25 is able to change the volume of liquid metal and to regulate thereby the inter-electrode distance.

Clearly, for the embodiments shown in FIGS. 1 and 2, electrodes will be conformal.

Preferably the liquid metal utilized in the present invention should have a low work function. One possible example is cesium, which has a melting temperature of 29° C. It could be mixed with some other liquid metal, such as gallium, to form a suitable mixture having a low work function. It should be noted that the width of tunneling barrier will be of the order of 50-100 nm in the case of liquid metal-surface junction, and therefore the extremely low width of tunnel barrier will allow use of higher work function electrodes.

In a further embodiment (not shown) the flat electrode surface could be covered with thin layer of an insulator to increase efficiency.

1. A diode device comprising:
(a) a first electrode;
(b) a second electrode; and
(c) a liquid metal disposed between said first and said second electrode;
wherein said liquid metal is in contact with first and said second electrode, and wherein said liquid metal does not wet said first electrode.

2. The diode device of claim 1 additionally comprising a non-wettable housing.

3. The diode device of claim 2 wherein said housing is cylindrical.

4. The diode device of claim 1 wherein said liquid metal has a low work function.

5. The diode device of claim 4 wherein said liquid metal comprises cesium.

6. The diode device of claim 1 wherein said liquid metal comprises gallium.

7. The diode device of claim 1 additionally comprising a piston means able to change a volume of the liquid metal.
